(19) United States
(12) Patent Application Publication
(10) Pub. No.: US 2022/0363835 A1
(43) Pub. Date: Nov. 17, 2022

(54) THERMALLY CONDUCTIVE SILICONE COMPOSITION AND METHOD FOR PRODUCING THE SAME

(71) Applicant: Fuji Polymer Industries Co., Ltd., Nagoyo-shi, Aichi (JP)

(72) Inventors: Makoto IWAI, Aichi (JP); Shingo KOBAYASHI, Aichi (JP); Yuko KIMURA, Aichi (JP)

(21) Appl. No.: 17/633,780

(22) PCT Filed: Apr. 2, 2021
(86) PCT No.: PCT/JP2021/014305

§ 371 Date: Feb. 8, 2022

(30) Foreign Application Priority Data
Sep. 3, 2020 (JP) 2020-148461

(51) Int. Cl. C08G 77/04; C08K 3/22; C08K 9/06; C08K 9/08; H01L 23/373

(52) U.S. Cl. CPC C08G 77/04; C08K 3/22; C08K 9/06; C08K 9/08; H01L 23/3737; C08K 2003/2227; C08K 2201/001; C08K 2201/005; C08K 2201/006

(57) ABSTRACT

A thermally conductive silicone composition contains a silicone polymer and a thermally conductive inorganic filler. The ratio X of the BET specific surface area (m²/g) to the average particle size (μm) of the thermally conductive inorganic filler is 0.1 or more. The thermally conductive inorganic filler is surface treated with a first surface treatment agent and further surface treated with a second surface treatment agent. The first surface treatment agent contains an organic silane compound represented by R¹¹SiR¹²ₓ(OR¹³)₃₋ₓ (where R¹¹ is, e.g., a monovalent aliphatic hydrocarbon group having 1 to 4 carbon atoms or a monovalent aromatic hydrocarbon group having 6 to 30 carbon atoms, R¹² is, e.g., a methyl group, and R¹³ is, e.g., a hydrocarbon group having 1 to 4 carbon atoms). The second surface treatment agent contains a silicone polymer that has a kinematic viscosity of 1000 mm²/s or less and does not have a hydrolyzable group. Thus, the present invention provides a thermally conductive silicone composition that has improved viscoelasticity and heat resistance, and a method for producing the thermally conductive silicone composition.

### TECHNICAL FIELD

The present invention relates to a thermally conductive silicone composition that is suitable to be interposed between a heat generating member and a heat dissipating material of electrical and electronic components or the like, and a method for producing the thermally conductive silicone composition.

### BACKGROUND ART

With the significant improvement in performance of semiconductor devices such as CPUs in recent years, the amount of heat generated by them has become extremely large. For this reason, heat dissipating materials are attached to electronic components such as semiconductor devices that may generate heat, and a thermally conductive silicone grease or sheet is used to improve the adhesion between the heat dissipating materials and the semiconductor devices. Patent Document 1 proposes a method for treating the surface of a thermally conductive inorganic filler with a silane coupling agent having a long chain alkyl group in order to reduce an increase in the viscosity of a slurry that is obtained by mixing the filler and a base polymer, and to improve extrudability and moldability. However, if the filler is composed of partides with a large specific surface area and a small particle diameter, it may not be sufficient to simply treat such a filler with the silane coupling agent having a long chain alkyl group in terms of preventing an increase in the viscosity of the slurry. Therefore, a further reduction in the viscosity of the slurry is desirable to improve extrudability and processability. Patent Documents 2 to 4 propose, as a solution to this problem, the use of a polymeric coupling agent to enhance the affinity between the surface of a filler and a polymer.

### PRIOR ART DOCUMENTS

Patent Documents

Patent Document 1: JP 3092127 B2

Patent Document 2: JP H10(1998)-045857 A

Patent Document 3: JP 2000-256558 A

Patent Document 4: JP 2009-221210 A

### DISCLOSURE OF INVENTION

### Problem to be Solved by the Invention

However, when the conventional polymeric surface treatment agent having a large molecular weight is in contact with an inorganic filler composed of particles with a large specific surface area and a small average particle size, the wettability of the surface of the inorganic filler can be reduced. Thus, the reactivity of the polymeric surface treatment agent with the surface of the inorganic filler may be poor. Moreover, a hydrolyzable functional group that does not react with the surface of the inorganic filler remains in the polymeric surface treatment agent and may have an adverse effect on the physical properties of a composite material produced by molding the mixture. As a result, the conventional technology still has problems with viscoelasticity and heat resistance.

To solve the above conventional problems, the present invention provides a thermally conductive silicone composition that has improved viscoelasticity and heat resistance by incorporating a thermally conductive inorganic filler that has been subjected to a multiple surface treatment, and a method for producing the thermally conductive silicone composition.

### Means for Solving Problem

A thermally conductive silicone composition of the present invention contains a silicone polymer as a matrix resin and a thermally conductive inorganic filler. A ratio X of a BET specific surface area to an average particle size of the thermally conductive inorganic filler is 0.1 or more, which is represented by the following formula (1):

X=A_{BET}/d₅₀ (1)

where A_{BET} is the BET specific surface area (m²/g) and d₅₀ is the average particle size (μm) of the thermally conductive inorganic filler. The thermally conductive inorganic filler is surface treated with a first surface treatment agent and further surface treated with a second surface treatment agent. The first surface treatment agent contains an organic silane compound represented by R¹¹SiR¹²ₓ(OR¹³)₃₋ₓ (where R¹¹ is a monovalent aliphatic hydrocarbon group having 1 to 4 carbon atoms, a monovalent aromatic hydrocarbon group having 6 to 30 carbon atoms, or a monovalent substituent represented by the following Chemical Formula (1), Chemical Formula (2), Chemical Formula (3), or Chemical Formula (4):

[Chemical Formula 1] R¹⁴_{y}R¹⁵_{3-y}SiOR¹⁶(CₙH₂ₙ)ₚ (1);

[Chemical Formula 2] [R¹³O_{3-z}R¹²_{z}Si](CₙH₂ₙ)ₚR¹⁶(CₙH₂ₙ)ₚ (2);

[Chemical Formula 3] [(R¹³O)_{3-z}R¹²_{z}SiO]R¹⁶ (3);

[Chemical Formula 4] [(R¹³O)_{3-z}R¹²_{z}Si]R¹⁷ (4),

R¹² is a methyl group or a phenyl group and may be the same or different, R¹³ is a hydrocarbon group having 1 to 4 carbon atoms and may be the same or different, R¹⁴ is a hydrocarbon group having 1 to 4 carbon atoms or a phenyl group and may include a double bond, R¹⁵ is a methyl group or a phenyl group, R¹⁶ is a divalent polysiloxane represented by (R¹⁸₂SiO)ₘ, R¹⁷ is a divalent aliphatic hydrocarbon group having 1 to 4 carbon atoms or a divalent aromatic hydrocarbon group having 6 to 30 carbon atoms, RIB is at least one selected from a methyl group and a phenyl group, xis 1 to 2, y is 1 to 3, z is 0 to 3, n is an integer of1 to 4, m is an integer of 1 to 20, and p is 0 or 1). The second surface treatment agent contains a silicone polymer that has a kinematic viscosity of 1000 mm²/s or less and does not have a hydrolyzable group.

A method for producing a thermally conductive silicone composition of the present invention provides the thermally conductive silicone composition as described above. A ratio X of a BET specific surface area to an average partide size of the thermally conductive inorganic filler is 0.1 or more, which is represented by the following formula (1):

X=A_{BET}/d₅₀ (1)

where A_{BET} is the BET specific surface area (m²/g) and d₅₀ is the average partide size (μm) of the thermally conductive inorganic filler. The method includes the following: surface treating the thermally conductive inorganic filler with a first surface treatment agent containing an organic silane compound represented by R¹¹SiR¹²ₓ(OR¹³)₃₋ₓ (where R¹¹, R¹², and R¹³ are the same as defined above); surface treating the thermally conductive inorganic filler with a second surface treatment agent containing a silicone polymer that has a kinematic viscosity of 1000 nam²/s or less and does not have a hydrolyzable group; and mixing the silicone polymer as the matrix resin and the thermally conductive inorganic filler that has been surface treated with the first surface treatment agent and the second surface treatment agent, and optionally curing the mixture.

### Effects of the Invention

The thermally conductive silicone composition of the present invention contains the thermally conductive inorganic filler that has a ratio X of the BET specific surface area to the average particle size of 0.1 or more, as represented by the formula (1), and that is surface treated with the first surface treatment agent and further surface treated with the second surface treatment agent. This configuration can improve viscoelasticity and heat resistance of the thermally conductive silicone composition. Moreover, the thermally conductive silicone composition can achieve a low slurry viscosity, high extrudability, and high moldability.

### BRIEF DESCRIPTION OF DRAWINGS

FIG. 1 a diagram illustrating a method for performing a heat resistance test (flexibility test) of a sample in an example of the present invention

FIG. 2 is a measurement photograph of a heat resistance test (flexibility test) of a sample in an example of the present invention

### DESCRIPTION OF THE INVENTION

The present inventors performed a first surface treatment of a thermally conductive inorganic filler (also referred to as an inorganic filler or inorganic particles in the following) with a particular silane coupling agent having good reactivity with the surface of the filler, and further performed a second surface treatment of the thermally conductive inorganic filler with a curable or non-curable silicone polymer that has a kinematic viscosity of 1000 mm²/s or less and does not have a hydrolyzable group. Then, the present inventors found that the use of the inorganic filler thus treated could improve viscoelasticity and heat resistance of the thermally conductive silicone composition Moreover, the thermally conductive silicone composition containing this inorganic filler was able to achieve a low slurry viscosity, high extrudability, and high moldability. It was also confirmed that the multiple surface treatment was significantly effective particularly for a thermally conductive filler composed ofparticles with a large specific surface area and a small particle diameter. In the context of the present invention, the multiple surface treatment means a plurality of surface treatments.

The thermally conductive silicone composition of the present invention contains a silicone polymer and a thermally conductive inorganic filler. The ratio X of a BET specific surface area to an average particle size of the thermally conductive inorganic filler is 0.1 or more, which is represented by the following formula (1):

X=A_{BET}/d₅₀ (1)

where Am is the BET specific surface area (m²/g) and d₅₀ is the average particle size of the thermally conductive inorganic filler.

The ratio X of the BET specific surface area to the average particle size takes into account the unevenness of the surface of the thermally conductive inorganic filler. When X is 0.1 or more, the inorganic filler has a large specific surface area and a small average particle size. This makes the multiple surface treatment of the present invention more effective. X is preferably 500 or less, more preferably 0.1 to 100, and further preferably 0.1 to 50. The matrix resin and the silicone polymer ofthe second surface treatment agent may be the same or different.

Two or more types of inorganic fillers with different X values may be used in combination. In such a case, the average of the X values is 0.1 or more.

The ratio X ofthe BET specific surface area to the average partide size of the thermally conductive inorganic filler is 0.1 or more, and the first surface treatment agent contains an organic silane compound represented by R¹¹SiR¹²ₓ(OR¹³)₃₋ₓ (where R¹¹, R¹², and R¹³ are the same as defined above) or an organic silane compound containing organic siloxane. Thus, the thermally conductive silicone composition can have high viscoelasticity and high heat resistance.

The thermally conductive inorganic filler is preferably composed of inorganic particles of at least one selected from aluminum oxide, zinc oxide, magnesium oxide, aluminum nitride, boron nitride, and aluminum hydroxide. These inorganic fillers can improve the thermal conductive properties.

The first surface treatment agent of the present invention contains an organic silane compound represented by R¹¹SiR¹²ₓ(OR¹³)₃₋ₓ (where R¹¹, R¹², and R¹³ are the same as defined above) or an organic silane compound containing organic siloxane. The organic silane compound and the organic silane compound containing organic siloxane are also referred to as a silane coupling agent. Examples of the silane coupling agent indude the flowing: methyltrimethoxysilane; ethyltrimethoxysilane; propyltrimethoxysilane (including n- and iso-); butyltrimethoxysilane (including n- and iso-); vinyltrimethoxysilane; vinyltriethoxysilane; allyltrimethoxysilane; phenyltrimethoxysilane; phenylethyltriethoxysilane; phenylpropyltsimethoxysilane; naphthyltrimethoxysilane; anthraoenyltrimethoxysilane; bis(trimethoxysilyl)benzene; bis(trimethoxysilyl)ethane; bis(trimethoxysilylethyObenzene; polysiloxane oligomer having trimethoxysilyl at both ends; polysiloxane oligomer having trimethoxysilyl at one end; and polydimethylsiloxane oligomer having trimethoxysilylethyl at one end. These silane coupling agents may be used individually or in combinations oftwo or more. In this case, the surface treatment may include adsorption in addition to a covalent bond. This allows the first surface treatment agent to be highly reactive with the surface of the inorganic filler.

The silane coupling agent is previously mixed with the thermally conductive inorganic filler, and optionally heated and pretreated. The heat treatment may be performed during the second surface treatment. The first surface treatment may be either a dry treatment or a wet treatment. In the dry treatment, the first surface treatment agent is directly scattered on the inorganic filler and mixed together. In the wet treatment, the first surface LN atment agent and a solvent are mixed and scattered on the inorganic filler, from which the solvent is then evaporated and removed. The dry treatment is suitable in terms of its operation. The silane coupling agent is applied preferably in an amount of 0.1 to 20 parts by mass, and more preferably in an amount of 0.5 to 10 parts by mass with respect to 100 parts by mass of the thermally conductive inorganic filler. The first surface treatment may further include a heating process at 80 to 180° C. for 1 to 24 hours in order to complete the treatment reaction

The second surface treatment agent ofthe present invention is a silicone polymer that has a kinematic viscosity of 1000 mm²/s or less and does not have a hydrolyzable group. The kinematic viscosity is measured at 25° C. using an Ubbelohde viscometer, and described in, e.g., the maniifactureis catalog. Examples of the second surface treatment agent include the following: polydimethylsiloxane having vinyldimethylsilyl at both ends (kinematic viscosity: 350 mm²/s); poly(vinylmethyldimethyl)siloxane having trimethylsilyl at both ends (kinematic viscosity: 750 mm²/s); polydimethylsiloxane having trimethylsilyl at both ends (kinematic viscosity: 300 mm²/s); poly(phenylmethyldimethyl)polysiloxane (kinematic viscosity 125 mm²/s); and polydimethylsiloxane having dimethylhydrogensilyl at both ends (kinematic viscosity: 100 mm²/s).

The second surface treatment agent is applied preferably in an amount of 0.1 to 30 parts by mass, and more preferably in an amount of 1 to 20 parts by mass with respect to 100 parts by mass of the thermally conductive inorganic filler. This configuration can reduce the slurry viscosity and improve the extrudability and moldability of the thermally conductive silicone composition. The surface treatment with the second surface treatment agent is preferably a dry treatment using a high-speed stirrer such as a Henschel mixer. The second surface treatment may be performed subsequent to the first surface treatment in the same surface treatment device. Alternatively, the inorganic filler that has been subjected to the first surface treatment may be put in another device, to which the second surface treatment agent may be added. Moreover, heating and decompression may be performed simultaneat isly in the surface treatment by high speed rotation. The second surface treatment may further indude a heating process at 80 to 180° C. for 1 to 24 hours in order to complete the treatment reaction. This heat treatment is desirable in terms of storage stability.

The content of the thermally conductive inorganic filler that has been subjected to the first surface treatment and the second surface treatment in the thermally conductive silicone composition is preferably 100 to 10000 parts by mass, more preferably 300 to 5000 parts by mass, and further preferably 500 to 900 parts by mass with respect to 100 parts by mass of the silicone polymer. This can improve the thermal conductive properties. The thermal conductivity is preferably 1 to 30 W/m·K, more preferably 1.2 to 10 W/m·K, and further preferably 1.5 to 5 W/m·K.

The thermally conductive silicone composition is preferably in the form of at least one selected from greasP, putty, gel, and rubber. These materials are suitable as a TIM (thermal interface material) to be interposed between a heat generating member such as a semiconductor device and a heat dissipating material.

The method for producing the thermally conductive silicone composition of the present invention indudes mixing the silicone polymer as the matrix resin and the thermally conductive inorganic filler that has been subjected to the first surface treatment and the second surface treatment, and optionally curing the mixture. The liquid materials such as grease and putty may not be cured. When a curing process is performed, a curing catalyst may be added. If the thermally conductive silicone composition is molded into, e.g., a sheet, a molding process is inserted between the mixing process and the curing process. The thermally conductive silicone composition in the form of a sheet is suitable for mounting on electronic components or the like. The thickness of the thermally conductive sheet is preferably 0.2 to 10 mm.

A compound with the following composition is preferably used to obtain a cured product.

A. Matrix Resin Component

The matrix resin component contains the Mowing components A1 and A2. In this case, the components A1 and A2 add up to 100 parts by mass.

A1: a linear organopolysiloxane having at least two silicon-bonded alkenyl groups per molecule.

A2: an organohydrogenpolysiloxane having at least two silicon-bonded hydrogen atoms per molecule, which serves as a crasslinking component.

The number of moles of the organohydrogenpolysiloxane is 0.5 to 2.0 moles with respect to 1 mole of the alkenyl groups contained in the component A1, the first surface treatment agent, and the second surface treatment agent.

When the second surface treatment agent contains a silicon-bonded hydrogen atom, it is preferable that the amount of the silicon-bonded hydrogen atom is also included in the number of moles of the organohydrogenpolysiloxane, as calculated above.

The matrix resin component may contain an organopolysiloxane having no reactive group other than the components A1 and A2.

B. Thermally Conductive Inorganic Filler

The amount of the thermally conductive inorganic filler that has been subjected to the first surface treatment and the second surface treatment is 100 to 10000 parts by mass.

C. Curing Catalyst

When the curing catalyst is (1) an addition reaction catalyst that is a platinum-based metal catalyst, the amount of the addition reaction catalyst is 0.01 to 1000 ppm by mass with respect to the matrix resin component. When the curing catalyst is (2) an organic peroxide catalyst, the amount of the organic peroxide catalyst is 0.5 to 30 parts by mass with respect to the matrix resin component.

D. Other Additives

Other additives such as a curing retarder and a coloring agent may be added in any amount.

Hereinafter, each component will be described.

(1) Base Polymer Component (Component A1)

The base polymer component is an organopolysiloxane containing two or more alkenyl groups bonded to silicon atoms per molecule. The organopolysiloxane containing two or more alkenyl groups is the base resin (base polymer component) of a silicone rubber composition of the present invention. In this case, the organopolysiloxane has two silicon-bonded alkenyl groups per molecule. The alkenyl group has 2 to 8 carbon atoms, and particularly 2 to 6 carbon atoms and can be, e.g., a vinyl group or an allyl group. The viscosity of the organopolysiloxane is preferably 10 to 1000000 mPa·s, and more preferably 100 to 100000 mPa·s at 25° C. in terms of workability and curability.

Specifically, an organopolysiloxane represented by the following general formula (Chemical Formula 5) is used. This organopolysiloxane contains two or more alkenyl groups per molecule, in which the alkenyl groups are bonded to silicon atoms at both ends of the molecular chain. The organopolysiloxane is a linear organopolysiloxane whose side chains are capped with alkyl groups. The viscosity of the organopolysiloxane is preferably 10 to 1000000 mPa·s at 25° C. in terms of workability and curability. Moreover, the linear organopolysiloxane may include a small amount of branched structure (trifunctional siloxane units) in the molecular chain.

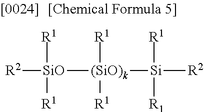

In the formula, R¹ represents substituted or unsubstituted monovalent hydrocarbon groups that are the same as or different from each other and have no aliphatic unsaturated bond, R² represents alkenyl groups, and k represents 0 or a positive integer. The monovalent hydrocarbon group represented by R¹ has, e.g., 1 to 10 carbon atoms, and more preferably 1 to 6 carbon atoms. Specific examples of the monovalent hydrocarbon group include the following: alkyl groups such as methyl, ethyl, propyl, isopropyl, butyl, isobutyl, tert-butyl, pentyl, neopentyl, hexyl, cyclohexyl, octyl, nonyl, and decyl groups; aryl groups such as phenyl, tolyl, xylyl, and naphthyl groups; aralkyl groups such as benzyl, phenylethyl, and phenylpropyl groups; and substituted forms of these groups in which some or all hydrogen atoms are substituted by halogen atoms (fluorine, bromine, chlorine, etc.) or cyano groups, including halogen-substituted alkyl groups such as chloromethyl, chloropropyl, bromoethyl, and trifluoropropyl groups and cyanoethyl groups. The alkenyl group represented by R² has, e.g., 2 to 6 carbon atoms, and more preferably 2 to 3 carbon atoms. Specific examples of the alkenyl group include vinyl, allyl, propenyl, isopropenyl, butenyl, isobutenyl, hexenyl, and cyclohexenyl groups. In particular, the vinyl group is preferred. In the general formula (Chemical Formula 5), k is typically 0 or a positive integer satisfying 0≤k≤10000, preferably 5≤k≤2000, and more preferably 10≤k≤1200.

The component A1 may also include an organopolysiloxane having three or more, typically 3 to 30, and preferably about 3 to 20, silicon-bonded alkenyl groups per molecule. The alkenyl group has 2 to 8 carbon atoms, and particularly 2 to 6 carbon atoms and can be, e.g., a vinyl group or an allyl group. The molecular structure may be a linear, ring, branched, or three-dimensional network structure. The organopolysiloxane is preferably a linear organopolysiloxane in which the main chain is composed of repeating diorganosiloxane units, and both ends of the molecular chain are capped with triorganosiloxy groups. The viscosity of the linear organopolysiloxane may be 10 to 1000000 mPa·s, and particularly 100 to 100000 mPa·s at 25° C.

Each of the alkenyl groups may be bonded to any part of the molecule. For example, the alkenyl group may be bonded to either a silicon atom that is at the end of the molecular chain or a silicon atom that is not at the end (but in the middle) of the molecular chain. In particular, a linear organopolysiloxane represented by the following general formula (Chemical Formula 6) is prethrred. The linear organopolysiloxane has 1 to 3 alkenyl groups on each of the silicon atoms at both ends of the molecular chain. In this case, however, if the total number of the alkenyl groups bonded to the silicon atoms at both ends of the molecular chain is less than 3, at least one alkenyl group is bonded to the silicon atom that is not at the end (but in the middle) of the molecular chain (e.g., as a substituent in the diorganosiloxane unit). As described above, the viscosity ofthe linear organopolysiloxane is preferably 10 to 1000000 mPa·s at 25° C. in terms of workability and curability. Moreover, the linear organopolysiloxane may include a small amount of branched structure (trifunctional siloxane units) in the molecular chain.

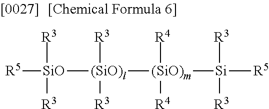

In the formula, R³ represents substituted or unsubstituted monovalent hydrocarbon groups that are the same as or different from each other, and at least one of them is an alkenyl group. R⁴ represents substituted or unsubstituted monovalent hydrocarbon groups that are the same as or different from each other and have no aliphatic unsaturated bond, R⁵ represents alkenyl groups, and 1 and m represent 0 or a positive integer. The monovalent hydrocarbon group represented by R³ preferably has 1 to 10 carbon atoms, and more preferably 1 to 6 carbon atoms. Specific examples of the monovalent hydrocarbon group include the following; alkyl groups such as methyl, ethyl, propyl, isopropyl, butyl, isobutyl, tert-butyl, pentyl, neopentyl, hexyl, cydohexyl, octyl, nonyl, and decyl groups; aryl groups such as phenyl, tolyl, xylyl, and naphthyl groups; aralkyl groups such as benzyl, phenylethyl, and phenylpropyl groups; alkenyl groups such as vinyl, allyl, propenyl, isopropenyl, butenyl, hexenyl, cydohexenyl, and octenyl groups; and substituted forms of these groups in which some or all hydrogen atoms are substituted by halogen atoms (fluorine, bromine, chlorine, etc.) or cyano groups, including halogen-substituted alkyl groups such as chloromethyl, chloropropyl, bromoethyl, and trifluoropiupyl groups and cyanoethyl groups.

The monovalent hydrocarbon group represented by R⁴ also preferably has 1 to 10 carbon atoms, and more preferably 1 to 6 carbon atoms. Specific examples of the monovalent hydrocarbon group may be the same as those of R′, but do not indude an alkenyl group. The alkenyl group represented by R⁵ has, e.g., 2 to 6 carbon atoms, and more preferably 2 to 3 carbon atoms. Specific Examples of the alkenyl group may be the same as those of R² in the formula (Chemical Formula 5), and the vinyl group is preferred. In the formula (Chemical Formula 6), 1 and m are typically 0 or positive integers satisfying 0<1+m≤10000, preferably 5≤1+m≤2000, and more preferably 10≤1+m≤1200. Moreover, 1 and m are integers satisfying 0<1/(1+m)≤0.2, and preferably 0.0011≤1/(1+m)≤0.1.

(2) Crosslinking Component (Component A2)

The component A2 is an organohydrogenpolysiloxane that acts as a crosslinking agent. The addition reaction (hydrosilylation) between SiH groups in the component A2 and alkenyl groups in the component A1 produces a cured product. Any organohydrogenpolysiloxane that has two or more silicon-bonded hydrogen atoms (ie., SiH groups) per molecule may be used. The molecular structure of the organohydrogenpolysiloxane may be a linear, ring, branched, or three-dimensional network structure. The number of silicon atoms in a molecule (i.e., the degree of polymerization) may be 2 to 1000, and particularly about 2 to 300.

The locations of the silicon atoms to which the hydrogen atoms are bonded are not particularly limited. The silicon atoms may be either at the ends or not at the ends (but in the middle) of the molecular chain. The silicon-bonded organic groups other than the hydrogen atoms maybe, e.g., substituted or unsubstituted monovalent hydrocarbon groups that have no aliphatic unsaturated bond, which are the same as those of R¹ in the general formula (Chemical Formula 5).

The organohydrogenpolysiloxane of the component A2 may have the following structure.

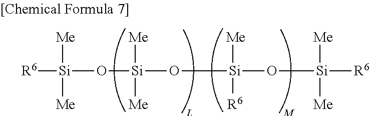

In the formula, R^{6′}are the same as or different from each other and represent alkyl groups, phenyl groups, epoxy groups, acryloyl groups, methacryloyl groups, alkoxy groups, or hydrogen atoms, and at least two of Ws are hydrogen atoms. L represents an integer of 0 to 1000, and particularly 0 to 300, and M represents an integer of 1 to 200.

(3) Catalyst Component (Component C)

The catalyst component of the component C may be a catalyst used for a hydrosilylation reaction. Examples of the catalyst include platinum group metal catalysts such as platinum-based, palladium-based, and rhodium-based catalysts. The platinum-based catalysts indude, e.g., platinum black, platinum chloride, chloroplatinic acid, a reaction product of chloroplatinic acid and monohydric alcohol, a complex of chloroplatinic add and olefin or vinylsiloxane, and platinum bisacetoacetath.

(4) Thermally Conductive Inorganic Filler (Component B)

The thermally conductive inorganic filler is as described above.

(5) Other Additives

The composition of the present invention may indude components other than the above as needed. For example, a heat resistance improver (such as colcothar, titanium oxide, or cerium oxide), a flame retardant auxiliary, and a curing retarder may be added. Moreover, an organic or inorganic pigment may be added for the purpose of coloring and toning.

### EXAMPLES

Hereinafter, the present invention will be described by way of examples. However, the present invention is not limited to the following examples. Various physical properties were measured in the following manner.

<Kinematic Viscosity>

The kinematic viscosity was measured at 25° C. using an Ubbelohde viscometer, and described in, e.g., the manufacturer's catalog.

<BET Specific Surface Area>

The BET specific surface area of a thermally conductive filler was the value of the manufacturer's catalog. The specific surface area means the surface area per unit mass or the surface area per unit volume of a substance. The specific surface area analysis is based on the adsorption of molecules on the surface of powder particles at a liquid nitrogen temperature. Since the area occupied by an adsorbed molecule has been known, the specific surface area of a sample is determined from the amount of the adsorbed molecules by using the BET equation.

<Average Particle Size>

The average particle size was D₅₀ (median diameter) in a volume-based cumulative particle size distribution measured by a laser diffraction scattering method. The method may use, e.g., a laser diffraction/sea ttering particle size distribution analyzer LA-950 S2 manufactured by HORIBA, Ltd.

<Shear Viscosity>

The shear viscosity was measured using a rheometer HAAKE MARS III (manufactured by Thermo Fisher Scientific KK) having parallel plates with a diameter (φ) of 10 mm under the conditions that the gap was 1.0 mm, the temperature was 23° C., and the shear rate was 1.0 (1/s).

<Thermal Conductivity>

The thermal conductivity of thermally conductive grease and the thermal conductivity of a thermally conductive silicone sheet were measured at 25° C. using DynTIM (manufactured by Mentor Graphics Japan Co., Ltd.).

<Heat resistance Rest of Thermally Conductive Silicone Grease>About 1.0 g of a sample of thermally conductive silicone grease was sandwiched between two glass slides separated by a polytetrafluoroethylene (PTFE) spacer with a thickness of 1.0 mm. The sample was secured with clips and held in a constant temperature oven at a predetermined temperature. Then, the state of the sample was observed after a certain period of time. The sample was evaluated as follows: (A) The sample was kept greasy; (B) The sample did not flow easily due to an increase in viscosity; (C) The sample was cured and not able to flow. The test was performed 3 times.

<Heat Resistance Test (Flexibility Test) of Thermally Conductive Silicone Sheet>

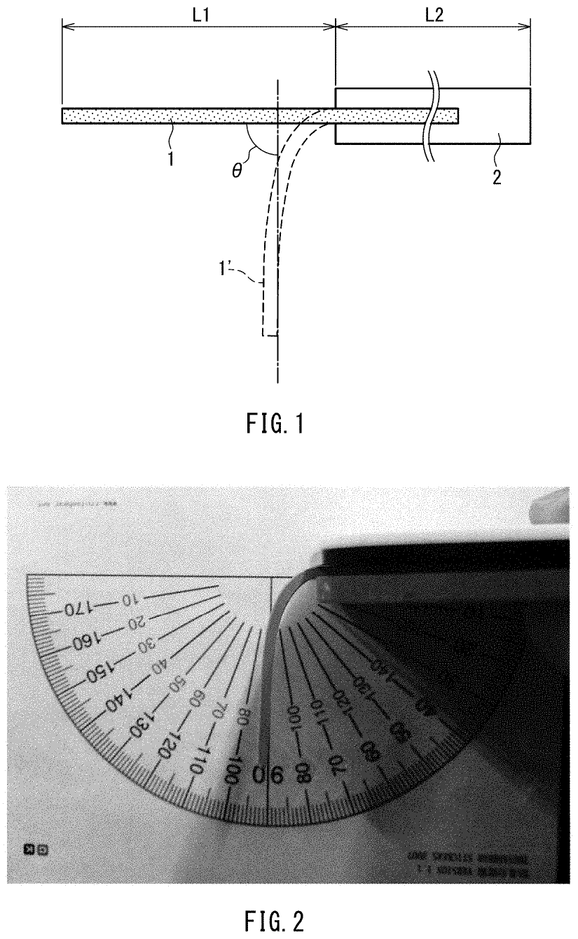

A silicone resin sheet 1 with a length of 100 mm, a width of 20 mm, and a thickness of 2 mm was prepared and heat treated at a predetermined temperature for a predetermined time. Then, as shown in FIG. 1, the silicone resin sheet 1 was held horizontally by a holder 2. In this ease, a portion of the silicone resin sheet 1, indicated by L1 (40 mm), was sticking out of the holder 2 and the remaining portion, indicated by L2 (60 mm), was located in the holder 2. Reference numeral 1′ represents the silicone resin sheet hanging down from the holder 2. An asymptote passing through the end portion of the silicone resin sheet 1′ hanging under its own. weight from the edge of the holder 2 was determined, and a bending angle θ between the asymptote and the horizontal line extending from the holder 2 was measured. The shorter the heat treatment time, the more likely the silicone resin sheet was to hang at right angles, i.e., to bend 90°. However, the silicone resin sheet would not bend as curing and degradation proceeded, and thus the angle approached zero. In other words, the larger the angle θ, the higher the heat resistance. The average of the results of three tests was obtained in the flexibility test. The heat resistance was evaluated by the bending angle θ (°) after the silicone resin sheet had been treated in the air at a predetermined temperature for a predetermined time.

FIG. 2 is a measurement photograph of the heat resistance test (flexibility test).

<Materials>

Examples and Comparative Examples used the following materials.

A Matrix resin (base oil)

(A-1) poly(phenylmethyldimethyl)siloxane: viscosity of 125 mm²/s

(A-2) polydimethylsiloxane with trimethylsilyl at both ends: viscosity of 300 mm²/s

(A-3a) two-part addition curable dimethyl silicone (solution a), vinyl functional dimethyl silicone polymer containing platinum catalyst: viscosity of 1000 mPa·s

(A-3b) two-part addition curable dimethyl silicone (solution b), mixture of vinyl functional dimethyl silicone polymer and SiH functional dimethyl silicone polymer: viscosity of 1000 mPa·s

B. Thermally Conductive Inorganic Filler

(B-1) crushed a alumina: BET specific surface area of 5.2 m²/g, average particle size of 2.10 μm, X=2.476

(B-2) fine powder a alumina: BET specific surface area of 6.7 m²/g, average particle size of 0.27 μm, X=24.815

(B-3) spherical fused alumina: BET specific surface area of 0.2 m²/g, average particle size of 38.0 μm, X=0.005

C. First Surface Treatment Agent

(C-1) methyltrimethoxysilane: molecular weight of 136.2

(C-2) phenyltrimethoxysilane: molecular weight of 198.29

(C-3) decyltrimethoxysilane: molecular weight of 262.5

D. Second Surface Treatment Agent

(D-1.) poly(phenylmethyldimethyl)siloxane: viscosity of 125 mm²/s

(D-2) polydimethylsiloxane with trimethylsilyl at both ends: viscosity of 300 mm²/s

### Example 1

<First Surface Treatment of Thermally Conductive Inorganic Filler>

First, a dry surface treatment of 150.0 g of crushed alumina LS243 (B-1) (BET specific surface area (A_{BET}): 5.2 m²/g, average particle size (d₅₀): 2.2 μm, X=2.476) with 1.0 g of methyltrimethoxysilane (C-1) (molecular weight: 136.2), which was the first surface treatment agent, was performed by using Wonder Crusher WC-3 (manufactured by OSAKA CHEMICAL Co., Ltd.).

<Second Surface Treatment of Thermally Conductive Inorganic Filler>

Then, the thermally conductive inorganic filler that had been subjected to the first surface treatment was surface treated with 1.0 g of poly(phenylmethyldimethyl)siloxane (D-1) (viscosity: 125 mm²/s), which was the second surface treatment agent, by using Wonder Crusher WC-3 (manufactured by OSAKA CHEMICAL Co, Ltd.). The resulting inorganic filler was heat treated at 120° C. for 6 hours. Thus, the double surface treated thermally conductive inorganic filler was obtained.

<Production of Thermally Conductive Compound>

The thermally conductive inorganic filler prepared in the above manner and the matrix resin were mixed according to the composition shown in Table 1 by using a rotation-revolution mixer (MAZERUSTAR KK-400W manufactured by KURABO INDUSTRIES LTD.) to provide a thermally conductive compound. The shear viscosity and thermal conductivity of the thermally conductive compound were measured. Table 1 shows the results of the measurement along with the results of the heat resistance test.

### (Examples 2 to 6, Comparative Examples 1 to 7)

Examples 2 to 6 and Comparative Examples 1 to 7 were performed in the same manner as Example 1 except that the composition was varied as shown in Table 1. Table 1 shows the conditions and the results. The mass of each filler was expressed as the amount (g) with respect to 100 g of the matrix resin.

TABLE 1

| | | Comp. | | Comp. | | | | Comp. | Comp. | Comp. | Comp. | Comp. |
|---|---|---|---|---|---|---|---|---|---|---|---|---|
| | Ex. 1 | Ex. 1 | Ex. 2 | Ex.2 | Ex. 3 | Ex. 4 | Ex. 5 | Ex. 3 | Ex. 4 | Ex. 5 | Ex. 6 | Ex. 7 |
| Matrix resin | (A-1) | (A-1) | (A-1) | (A-1) | (A-2) | (A-2) | (A-2) | (A-2) | (A-2) | (A-2) | (A-1) | (A-1) |
| mass (g) | 100.0 | 100.0 | 100.0 | 100.0 | 100.0 | 100.0 | 100.0 | 100.0 | 100.0 | 100.0 | 100.0 | 100.0 |
| Thermally conductive inorganic | (B-1) | (B-1) | (B-2) | (B-2) | (B-1) | (B-1) | (B-1) | (B-1) | (B-1) | (B-1) | (B-3) | (B-3) |
| filler (raw material | 493.4 | 472.9 | 350.9 | 315.3 | 493.4 | 492.2 | 493.4 | 496.7 | 495.0 | 468.2 | 663.8 | 666.2 |
| equivalent) mass (g) | | | | | | | | | | | | |
| First surface treatment agent | (C-1) | (C-1) | (C-2) | (C-2) | (C-1) | (C-2) | (C-1) | None | (C-3) | (C-3) | (C-2) | (C-2) |
| (raw material equivalent) mass (g) | 3.30 | 3.14 | 11.9 | 10.7 | 3.30 | 4.60 | 3.30 | — | 5.00 | 4.66 | 0.87 | 0.80 |
| Second surface treatment agent | (D-1) | None | (D-1) | None | (D-2) | (D-2) | (D-1) | (D-2) | None | (D-2) | (D-1) | None |
| (raw material equivalent) mass (g) | 3.30 | — | 12.2 | — | 3.30 | 3.30 | 3.30 | 3.30 | — | 3.14 | 2.33 | — |
| Amount of first surface treatment | 0.67 | 0.66 | 3.40 | 3.40 | 0.67 | 0.93 | 0.67 | 0.00 | 1.01 | 1.00 | 0.13 | 0.12 |
| agent added to filler (wt %) | | | | | | | | | | | | |
| Total amount of matrix resin and | 103.3 | 100.0 | 112.2 | 100.0 | 103.3 | 103.3 | 103.3 | 103.3 | 100.0 | 103.1 | 102.3 | 100.0 |
| second surface treatment agent (g) | | | | | | | | | | | | |
| Calculated value of amount of | 82.7 | 82.5 | 75.8 | 75.9 | 82.7 | 82.7 | 82.7 | 82.8 | 83.2 | 81.9 | 86.6 | 86.9 |
| thermally conductive inorganic | | | | | | | | | | | | |
| filler added (wt %) | | | | | | | | | | | | |
| Shear viscosity | 211 | 2090 | 2490 | (*1) | 310 | 279 | 223 | 966 | 342 | 301 | 619 | 572 |
| (Pa · s) | | | | | | | | | | | | |
| Thermal conductivity | 1.3 | 1.3 | 1.0 | (*1) | 1.3 | 1.3 | 1.3 | 1.3 | 1.3 | 1.3 | 0.8 | 0.8 |
| (W/m · K) | | | | | | | | | | | | |
| Heat resistance test | A | A-B | A | B | A | A | A | B | C | C | A | A |
| 220° C. × 230 h (*2) | | | | | | | | | | | | |

(*1) Not measurable due to extremely high viscosity
(*2) A: The compound was kept greasy, B: The compound did not flow easily, C: The compound was cured.

As can be seen from Table 1, the shear viscosity of the thermally conductive compound of Example 1, in which the inorganic filler had been subjected to the first surface treatment and the second surface treatment, was as low as about one-tenth of the shear viscosity of the thermally conductive compound of Comparative Example 1, in which the inorganic filler had not been subjected to the second surface Matment, although these compounds contained approximately the same amount of the inorganic filler and had the same thermal conductivity. Moreover, the heat resistance was better in Example 1 than in Comparative Example 1. Similarly, the thermally conductive compound of Example 2 was superior to that of Comparative Example 2. Examples 3 to 5 also ensured the effects of the present invention. In Comparative Example 3, the inorganic filler had been subjected to only the second surface treatment. The results of Comparative Example 3 confirmed that the effects of the present invention cannot be achieved unless the first surface treatment is performed. Further, the results of Comparative Examples 4 and 5 confirmed that the heat resistance can be reduced even if the second surface treatment is performed, when the first surface treatment agent is a silane coupling agent containing a hydrocarbon group having 10 carbon atoms (the second surface treatment was not performed in Comparative Example 4, but was performed in Comparative Example 5). Furthermore, the results of Comparative Examples 6 and 7 confirmed that the effects of the present invention cannot be achieved when the thermally conductive inorganic filler has a large average particle size and a small specific surface area (i.e., the value X is 0.005).

### Example 7

<Examples and Comparative Examples of Thermally Conductive Silicone Sheet>

According to the composition shown in Table 2, compounds were produce. Each of the compounds was sandwiched between polyethylene terephthalate (PET) films, which had been subjected to a release treatment, and molded into a sheet with a thickness of 2.0 mm by a roll press. Then, the sheet was heated at 100° C. for 30 minutes and cured to form a silicone gel sheet. The Asker C hardness and thermal conductivity of the thermally conductive silicone gel sheet thus obtained were measured after curing. Table 2 shows the results of the measurement along with the results of the heat resistance test concerning the flexibility.

### Examples 8 to 10, Comparative Examples 8 to 9)

Examples 8 to 10 and Comparative Examples 8 to 9 were performed in the same manner as Example 7 except that the composition was varied as shown in Table 2. Table 2 shows the conditions and the results. The mass of each filler was expressed as the amount (g) with respect to 100 g of the matrix resin.

TABLE 2

| | | | | | | | | | Comp. | | Comp. | |
|---|---|---|---|---|---|---|---|---|---|---|---|---|
| | Ex. 7 | | Ex. 8 | | Ex. 9 | | Ex. 10 | | Ex. 8 | | Ex. 9 | |
| Matrix resin 1 | (A-3a) | (A-3b) | (A-3a) | (A-3b) | (A-3a) | (A-3b) | (A-3a) | (A-3b) | (A-3a) | (A-3b) | (A-3a) | (A-3b) |
| mass (g) | 100.0 | 100.0 | 100.0 | 100.0 | 100.0 | 100.0 | 100.0 | 100.0 | 100.0 | 100.0 | 100.0 | 100.0 |
| Matrix resin 2 | (A-2) | (A-2) | (A-2) | (A-2) | (A-2) | (A-2) | (A-2) | (A-2) | (A-2) | (A-2) | (A-2) | (A-2) |
| mass (g) | 11.3 | 11.3 | 11.3 | 11.3 | 11.3 | 11.3 | 11.3 | 11.3 | 11.3 | 11.3 | 11.1 | 11.1 |
| Thermally conductive inorganic | (B-2) | (B-2) | (B-2) | (B-2) | (B-2) | (B-2) | (B-2) | (B-2) | (B-2) | (B-2) | (B-2) | (B-2) |
| filler 1 (raw material | 117.0 | 117.0 | 117.0 | 117.0 | 117.0 | 117.0 | 117.0 | 117.0 | 120.9 | 120.9 | 119.3 | 119.3 |
| equivalent) mass (g) | | | | | | | | | | | | |
| First surface treatment agent | (C-2) | (C-2) | (C-2) | (C-2) | (C-2) | (C-2) | (C-2) | (C-2) | (C-2) | (C-2) | (C-2) | (C-2) |
| (raw material equivalent) mass (g) | 3.98 | 3.98 | 3.98 | 3.98 | 3.98 | 3.98 | 3.98 | 3.98 | 4.11 | 4.11 | 2.68 | 2.68 |
| Second surface treatment agent | (D-1) | (D-1) | (D-1) | (D-1) | (D-1) | (D-1) | (D-1) | (D-1) | None | None | None | None |
| (raw material equivalent) mass (g) | 4.08 | 4.08 | 4.08 | 4.08 | 4.08 | 4.08 | 4.08 | 4.08 | — | — | — | — |
| Thermally conductive inorganic | (B-1) | (B-1) | (B-1) | (B-1) | (B-1) | (B-1) | (B-1) | (B-1) | (B-1) | (B-1) | (B-1) | (B-1) |
| filler 2 (raw material | 492.2 | 492.2 | 480.9 | 480.9 | 493.4 | 493.4 | 493.4 | 493.4 | 495.4 | 495.4 | 495.0 | 495.0 |
| equivalent) mass (g) | | | | | | | | | | | | |
| First surface treatment agent | (C-2) | (C-2) | (C-2) | (C-2) | (C-1) | (C-1) | (C-1) | (C-1) | (C-2) | (C-2) | (C-3) | (C-3) |
| (raw material equivalent) mass (g) | 4.60 | 4.60 | 4.50 | 4.50 | 3.30 | 3.30 | 3.30 | 3.30 | 4.6 | 4.6 | 4.95 | 4.95 |
| Second surface treatment agent | (D-2) | (D-2) | (D-1) | (D-1) | (D-2) | (D-2) | (D-1) | (D-1) | None | None | None | None |
| (raw material equivalent) mass (g) | 3.30 | 3.30 | 14.60 | 14.60 | 3.30 | 3.30 | 3.30 | 3.30 | — | — | — | — |
| Thermally conductive inorganic | (B-3) | (B-3) | (B-3) | (B-3) | (B-3) | (B-3) | (B-3) | (B-3) | (B-3) | (B-3) | (B-3) | (B-3) |
| filler 3 (raw material | 1110 | 1110 | 1110 | 1110 | 1110 | 1110 | 1110 | 1110 | 1110 | 1110 | 1110 | 1110 |
| equivalent) mass (g) | | | | | | | | | | | | |

| | | | | | | |
|---|---|---|---|---|---|---|
| Asker-C hardness after 10 seconds | 50 | 37 | 53 | 51 | 56 | 47 |
| Thermal conductivity | 3.7 | 3.1 | 3.8 | 4.0 | 4.2 | 3.6 |
| (W/m · K) | | | | | | |
| Heat resistance test | 90→40 | 90→50 | 90→45 | 90→50 | 90→25 | 90→0 |
| (220° C. × 300 h) | | | | | | |
| Bending angle (°): initial after test | | | | | | |

As can be seen from Table 2, the heat resistance of the thermally conductive silicone sheets of Examples 7 to 10, in which the inorganic filler had been subjected to the first surface treatment and the second surface treatment, was better than the heat resistance of the thermally conductive silicone sheets of Comparative Examples 8 to 9, in which the inorganic filler had not been subjected to the second surface treatment.

The above results confirmed that both viscoelasticity and heat resistance are high in Examples.

### INDUSTRIAL APPLICABILITY

The thermally conductive silicone composition of the present invention is suitable to be interposed between a heat generating member and a heat dissipating material of electrical and electronic components or the like.

### DESCRIPTION OF REFERENCE NUMERALS

1,1′ Thermally conductive silicone sheet

2 Holder

θ Angle

1. A thermally conductive silicone composition comprising:
a silicone polymer as a matrix resin; and
a thermally conductive inorganic filler,
wherein a ratio X of a BET specific surface area to an average particle size of the thermally conductive inorganic filler is 0.1 or more, which is represented by the following formula (1):
X=A_{BET}/d₅₀ (1)
where A_{BET} is the BET specific surface area (m²/g) and d₅₀ is the average particle size (μm)) of the thermally conductive inorganic filler,
wherein the thermally conductive inorganic filler is surface treated with a first surface treatment agent and further surface treated with a second surface treatment agent,
the thermally conductive inorganic filler is heat treated during the surface treatment with the first surface treatment agent and the surface treatment with the second surface treatment agent before the silicone polymer as the matrix resin and the thermally conductive inorganic filler are mixed to form the composition,
the first surface treatment agent contains an organic silane compound represented by R¹¹SiR¹²ₓ(OR¹³)₃₋ₓ (where R¹¹ is a monovalent aliphatic hydrocarbon group having 1 to 4 carbon atoms, a monovalent aromatic hydrocarbon group having 6 to 30 carbon atoms, or a monovalent substituent represented by the following Chemical Formula (1), Chemical Formula (2), Chemical Formula (3), or Chemical Formula (4):
R¹⁴_{y}R¹⁵_{3-y}SiOR¹⁶(CₙH₂ₙ)ₚ (1);
[(R¹³O)_{3-z}R¹²_{z}Si](CₙH₂ₙ)ₚR¹⁶(CₙH₂ₙ)ₚ (2);
[(R¹³O)_{3-z}R¹²_{z}SiO]R¹⁶ (3);
[(R¹³O)_{3-z}R¹²_{z}Si]R¹⁷ (4),
R¹² is a methyl group or a phenyl group and may be the same or different,
R¹³ is a hydrocarbon group having 1 to 4 carbon atoms and may be the same or different,
R¹⁴ is a hydrocarbon group having 1 to 4 carbon atoms or a phenyl group and may include a double bond,
R¹⁵ is a methyl group or a phenyl group,
R¹⁶ is a divalent polysiloxane represented by (R¹⁸₂SiO)ₘ,
R¹⁷ is a divalent aliphatic hydrocarbon group having 1 to 4 carbon atoms or a divalent aromatic hydrocarbon group having 6 to 30 carbon atoms,
R¹⁸ is at least one selected from the group consisting of a methyl group and a phenyl group, x is 0 to 2, y is 1 to 3, z is 0 to 3, n is an integer of 1 to 4, m is an integer of 1 to 20, and p is 0 or 1), and
the second surface treatment agent contains a silicone polymer that has a kinematic viscosity of 1000 mm²/s or less and does not have a hydrolyzable group.

2. The thermally conductive silicone composition according to claim 1, wherein a content of the thermally conductive inorganic filler that has been surface treated with the first surface treatment agent and the second surface treatment agent is 100 to 10000 parts by mass with respect to 100 parts by mass of the silicone polymer as the matrix resin.

3. The thermally conductive silicone composition according to claim 1, wherein the first surface treatment agent is applied in an amount of 0.1 to 50 parts by mass with respect to 100 parts by mass of the thermally conductive inorganic filler.

4. The thermally conductive silicone composition according to claim 1, wherein the second surface treatment agent is applied in an amount of 0.1 to 50 parts by mass with respect to 100 parts by mass of the thermally conductive inorganic filler.

5. The thermally conductive silicone composition according to claim 1, wherein an upper limit of X represented by the formula (1) is 500 or less.

6. The thermally conductive silicone composition according to claim 1, wherein R¹¹ of the first surface treatment agent is an aliphatic hydrocarbon group having 1 to 4 carbon atoms or an aromatic hydrocarbon group having 6 to 30 carbon atoms.

7. The thermally conductive silicone composition according to claim 1, wherein the thermally conductive inorganic filler is composed of inorganic particles of at least one selected from the group consisting of aluminum oxide, zinc oxide, magnesium oxide, aluminum nitride, boron nitride, and aluminum hydroxide.

8. The thermally conductive silicone composition according to claim 1, wherein the thermally conductive silicone composition is in the form of at least one selected from the group consisting of grease, putty, gel, and rubber.

9. A method for producing a thermally conductive silicone composition comprising a silicone polymer as a matrix resin and a thermally conductive inorganic filler,
wherein a ratio X of a BET specific surface area to an average particle size of the thermally conductive inorganic filler is 0.1 or more, which is represented by the following formula (1):
X=A_{BET}/d₅₀ (1)
where A_{BET} is the BET specific surface area (m²/g) and d₅₀ is the average particle size (μm) of the thermally conductive inorganic filler,
the method comprising:
surface treating the thermally conductive inorganic filler with a first surface treatment agent;
surface treating the thermally conductive inorganic filler with a second surface treatment agent;
heat treating the thermally conductive inorganic filler during the surface treatment with the first surface treatment agent and the surface treatment with the second surface treatment agent and then
mixing the silicone polymer as the matrix resin and the thermally conductive inorganic filler that has been surface treated with the first surface treatment agent and the second surface treatment agent, and optionally curing the mixture,
wherein the first surface treatment agent contains an organic silane compound represented by R¹¹SiR¹²ₓ(OR¹³)₃₋ₓ (where R¹¹ is a monovalent aliphatic hydrocarbon group having 1 to 4 carbon atoms, a monovalent aromatic hydrocarbon group having 6 to 30 carbon atoms, or a monovalent substituent represented by the following Chemical Formula (1), Chemical Formula (2), Chemical Formula (3), or Chemical Formula (4):
R¹⁴_{y}R¹⁵_{3-y}SiOR¹⁶(CₙH₂ₙ)ₚ (1);
[(R¹³O)_{3-z}R¹²_{z}Sᵢ](CₙH₂ₙ)ₚR¹⁶(CₙH₂n)ₚ (2);
[(R¹³O)_{3-z}R¹²_{z}SiO]R¹⁶ (3);
[(R¹³O)_{3-z}R¹²_{z}Si]R¹⁷ (4),
R¹² is a methyl group or a phenyl group and may be the same or different,
R¹³ is a hydrocarbon group having 1 to 4 carbon atoms and may be the same or different,
R¹⁴ is a hydrocarbon group having 1 to 4 carbon atoms or a phenyl group and may include a double bond,
R¹⁵ is a methyl group or a phenyl group,
R¹⁶ is a divalent polysiloxane represented by (R¹⁸₂SiO)ₘ,
R¹⁷ is a divalent aliphatic hydrocarbon group having 1 to 4 carbon atoms or a divalent aromatic hydrocarbon group having 6 to 30 carbon atoms, R¹⁸ is at least one selected from the group consisting of a methyl group and a phenyl group, xis 0 to 2, y is 1 to 3, z is 0 to 3, n is an integer of 1 to 4, m is an integer of 1 to 20, and p is 0 or 1), and
the second surface treatment agent contains a silicone polymer that has a kinematic viscosity of 1000 mm²/s or less and does not have a hydrolyzable group.

10. The method according to claim 9, wherein the process using the first surface treatment agent includes a heating process at 80 to 180° C. for 1 to 24 hours, and further the process using the second surface treatment agent includes a heating process at 80 to 180° C. for 1 to 24 hours.

11. The method according to claim 9, wherein the curing is carried out, the method further comprising a molding process between the mixing process and the curing process.
